(19) United States
(12) Patent Application Publication
(10) Pub. No.: US 2005/0271223 A1
(43) Pub. Date: Dec. 8, 2005

(54) Audio signal reproducing method and reproducing apparatus

(76) Inventors: Tetsunori Itabashi, Kanagawa (JP); Kohei Asada, Kanagawa (JP)

Correspondence Address: COOPER & DUNHAM, LLP, 1185 AVENUE OF THE AMERICAS, NEW YORK, NY, 10036, US

(21) Appl. No.: 10/532,546

(22) PCT Filed: Oct. 23, 2003
(86) PCT No.: PCT/JP03/13574

§ 371 Date: Apr. 22, 2005

(30) Foreign Application Priority Data
Dec. 9, 2002 (JP) 2002-356139

(51) Int. Cl. H03G 5/00

(52) U.S. Cl. 381/98; 700/94

(57) ABSTRACT

A reproducing apparatus for an audio signal includes a number of digital filters, each supplied with an audio signal, and a speaker array in a configuration in which speakers are specially arranged. Outputs of the digital filters are delivered to the speakers. Predetermined delay times are respectively set at the digital filters, so that sound waves radiated from the speakers are reflected on wall surfaces, and then arrive at a sound field to form a place having sound pressure larger than that therearound within the sound field. Outputs of a second set of digital filters are delivered to the speakers. Predetermined delay times are respectively set at the second set of digital filters so as to suppress leakage sound which directly arrives at a place having large sound pressure from the speakers among sounds formed from outputs of the digital filters.

### TECHNICAL FIELD

The present invention relates to a reproducing method and a reproducing apparatus for an audio signal, which are suitable when applied to home theater, etc.

This Application claims priority of Japanese Patent Application No. 2002-356139, filed on Dec. 9, 2002, the entirety of which is incorporated by reference herein.

### BACKGROUND ART

As a speaker system suitable when applied to home theater and/or AV (Audio and Visual) system, etc., there is such a speaker array as described in the Japanese Patent Application Laid Open No. 1990-239798 publication (e.g., see Patent Literature 1). FIG. 1 shows one example of the speaker array 10. The speaker array 10 is caused to be of the configuration in which a large number of speakers (speaker units) SP0 to SPn are arranged. In this case, as an example, n is equal to 255 and the aperture of the speaker is several centimeters. Accordingly, while speakers SP0 to SPn are two-dimensionally arranged on the plane in practice, speakers SP0 to SPn are assumed to be arranged in line in a horizontal direction for the brevity.

Further, an audio signal is delivered from a source SC to delay circuits DL0 to DLn, at which the audio signals thus delivered are delayed by predetermined times τ0 to τn. The audio signals thus delayed are respectively delivered to speakers SP0 to SPn through power amplifiers PA0 to PAn. In this case, delay times τ0 to τn of the delay circuits DL0 to DLn will be described later.

Thus, also at all places, sound waves outputted from the speakers SP0 to SPn are synthesized so that sound pressure of the synthesized result can be obtained. In view of the above, as shown in FIG. 1, in the sound field formed by the speakers SP0 to SPn, in order to allow sound pressure of an arbitrary place Ptg to have a value higher than that therearound,
when L0 to Ln are distances from respective speakers SP0 to SPn to the place Ptg, and s is sound velocity, it is sufficient to set delay times τ0 to τn of the delay circuits DL0 to DLn as follows.
τ0=(Ln−L0)/s
τ1=(Ln−L1)/s
τ2=(Ln−L2)/s
. . .
τn=(Ln−Ln)/s=0

In the case where setting is made in a manner as stated above, an audio signal outputted from the source SC is converted into sound waves by the speakers SP0 to SPn and the sound waves thus converted are outputted, those sound waves would be outputted in a manner delayed by times τ0 to τn indicated by the above-mentioned formulas. Accordingly, when those sound waves arrive at the place Ptg, they would all arrive thereat at the same time. Thus, sound pressure at the place Ptg becomes larger than sound pressures therearound.

Namely, the speaker array 10 has directivity in sound pressure. Thus, in such a manner that parallel light is focused by convex lens, sound waves outputted from the speakers SP0 to SPn are converged onto the place Ptg. For this reason, the place Ptg will be called “focal point” hereinafter, and the speaker array 10 will be called focus type system.

Further, in the case where speaker array 10 as described above is used in the home theater, etc. to form sound field of 2 (two) channel stereo system, there can result arrangement and state, e.g., as shown in FIG. 2. Namely, in FIG. 2, reference numeral RM indicates rectangular room (closed space) serving as reproduction sound field, and speaker arrays 10L, 10R of left and right channels which are similar to the speaker array 10 are respectively disposed at the left side and at the right side of wall surface WLF of the front face of listener LSNR.

Further, when virtual image RM′ of room RM is considered with the wall surface WLL of the left side being as center as shown in FIG. 3, it can be considered that this virtual image RM′ is equivalent to the closed space of FIG. 2. Accordingly, focal point Ptg of the speaker array 10L is set to virtual image LSNR′ of the listener LSNR.

Thus, also as shown in FIG. 2, sound wave A WL radiated from the speaker array 10L is reflected at the position where linear line connecting the speaker array 10L and the virtual image LSNR′ is crossed (passed) on the wall surface WLL. As a result, focal point Ptg would be formed at the position of listener LSNR. Similarly, sound wave A WR radiated from the speaker array 10R is reflected at the position where linear line connecting speaker array 10R and virtual image of the listener LSNR is crossed (passed) on the wall surface WLR of the right side. As a result, focal point Ptg is formed at the position of the listener LSNR.

Accordingly, focal points Ptg of left and right channels are formed at the position of listener LSNR. Thus, the listener LSNR can strongly perceive sound image. At this time, the listener LSNR perceives respective virtual speakers in directions of virtual image 10L′ (see FIG. 3) of the speaker array 10L and virtual image of the speaker array 10R. Accordingly, the listener can perceive stereo-feeling broader than installation interval between the speaker arrays 10L, 10R.

Moreover, FIG. 4 shows the case where sound field of 4 (four) channel stereo system is formed. In this case, sound waves A WL, A WLB of left forward channel and left backward channel are radiated by, e.g., odd and even speakers of the speaker array 10L of the left channel, and the sound wave A WL is caused to be reflected on the wall surface WLL, and is then focused on the position of the listener LSNR. The sound wave A WLB is caused to be reflected on the wall surface WLL and the backward wall surface WLB, and is then focused on the focal point of the position of the listener LSNR. Similarly, sound waves A WR, A WRB of right forward channel and right backward channel are radiated by, e.g., odd and even speakers of the speaker array 10R of the right channel, and are caused to be reflected on the wall surfaces WLR, WLB, and are then focused on the position of listener LSNR.

In this case, even if no speaker is dispsed at the backward position of the listener LSNR, it is possible to form stereo sound field of surround system.

The representative example in the case where the speaker array is used to form sound field has been described above.

Meanwhile, in actual speaker array 10, when respective sound waves are radiated from speakers SP0 to SPn, those sound waves are spread from the speakers SP0 to SPn toward substantially all directions of the sound field. For this reason, also as shown in FIG. 5, listener LSNR listens to primary sound wave A WL which is reflected on the wall surface WLL and is then reached to the position of the listener LSNR, and also listens to sound wave A Wnc which arrives at the listener LSNR directly from the spaker array 10. So to speak, “leakage sound A Wnc” would be heard from the speaker array 10L to the listener LSNR.

In this case, since delay times τ0 to τn are set so that those time delays coincide with each other at the position of the listener LSNR with respect to respective sound waves constituting primary sound wave A WL, respective sound waves constituting leakage sound A Wnc would have time delays varied from each other. Accordingly, even if respective sound waves are synthesized at the position of the listener LSNR, its sound pressure does not become large. Namely, sound pressure of leakage sound A Wnc is smaller than that of primary sound wave A WL.

However, even if sound pressure of the leakage sound A Wnc is small, time delays of respective sound waves constituting the leakage sound A Wnc are varied with respect to primary sound wave A WL.

For this reason, at the same time when listener LSNR listens to primary sound wave A WL, he would listen to leakage sound A Wnc having a time delay with respect to the sound wave A WL. Further, this similarly applies to the speaker array 10R of the right channel, the sound wave A WR and the leakage sound A Wnc thereof. As a result, qualities of reproduction sounds of the speaker arrays 10L, 10R are lowered by leakage sounds A Wnc, A Wnc.

In addition, in the case where paths of primary sound waves A WL, A WR are long, time difference between primary sound waves A WL, A WR and leakage sounds A Wnc, A Wnc becomes large. Thus, both sounds would be heard in a separated manner. For example, in the case of the speaker system of the surround stereo shown in FIG. 4, since paths of sound waves A WLB, A WRB of the backward channel are longer than paths of sound waves A WL, A WR of the speaker system of 2 (two) channel stereo shown in FIG. 2, time difference between sound waves A WLB, A WRB and leakage sounds A Wnc, A Wnc becomes longer. Thus, both sounds can be heard in more clearly separated manner.

### DISCLOSURE OF THE INVENTION

An object of the present invention is to provide a novel reproducing method for audio signal and a novel reproducing apparatus for audio signal which can solve problems that prior arts as described above have.

A reproducing method for audio signal according to the present invention comprises: delivering an audio signal to respective first plural digital filters; delivering outputs of the first plural digital filters to respective plural speakers constituting a speaker array to form sound field; respectively setting predetermined delay times at the first plural digital filters so that respective propagation delay times required until the audio signal arrives at a first point within the sound field through the first plural digital filters and the respective plural speakers coincide with each other; respectively delivering the audio signal to second plural digital filters; respectively delivering outputs of the second plural digital filters to the plural speakers; and respectively setting predetermined transfer characteristics at the second plural digital filters so as to control sound at a second point within the sound field among sounds formed from outputs of the first plural digital filters.

Another reproducing method for audio signal according to the present invention comprise: delivering an audio signal to respective first plural digital filters; delivering outputs of the first plural digital filters to respective plural speakers constituting a first speaker array to form sound field; respectively setting predetermined delay times at the first plural digital filters so that respective propagation delay times required until the audio signal arrives at a first point within the sound field through the first plural digital filters and the respective speakers of the first speaker array coincide with each other; delivering the audio signal to respective second plural digital filters; delivering outputs of the second plural digital filters to respective plural speakers constituting a second speaker array; and respectively setting predetermined transfer characteristics at the second plural digital filters so as to control sound at a second point within the sound field among sounds formed from outputs of the first plural digital filters.

A reproducing apparatus for audio signal according to the present invention includes first plural digital filters each supplied with an audio signal; second plural digital filters each supplied with the audio signal; and a speaker array caused to be of the configuration in which plural speakers are arranged to deliver outputs of the first plural digital filters to the respective plural speakers to form sound field to respectively set predetermined delay times at the first plural digital filters so that respective propagation delay times required until the audio signal arrives at a first point within the sound field through the first plural digital filters and the respective plural speakers coincide with each other to deliver outputs of the second plural digital filters to the respective plural speakers to respectively set predetermined transfer characteristics at the second plural digital filters so as to control sound at a second point within the sound field among sounds formed from outputs of the first plural digital filters.

The reproducing apparatus for audio signal further includes plural subtraction circuits respectively supplied with outputs of the first plural digital filters and outputs of the second plural digital filters to respectively deliver outputs of the plural subtraction circuits to the respective plural speakers.

Another reproducing apparatus for audio signal according to the present invention includes first plural digital filters each supplied with an audio signal; second plural digital filters each supplied with the audio signal; a first speaker array caused to be of the configuration in which plural speakers are arranged; and a second speaker array caused to be of the configuration in which plural speakers are arranged to deliver outputs of the first plural digital filters to the respective plural speakers constituting the first speaker array to form sound field to respectively set predetermined delay times at the first plural digital filters so that respective propagation delay times required until the audio signal arrives at a first point within the sound field through the first plural digital filters and the respective speakers of the first speaker array coincide with each other to deliver the audio signal to the respective second plural digital filters to deliver outputs of the second plural digital filters to respective plural speakers constituting a second speaker array to respectively set predetermined transfer characteristics at the second plural digital filters so as to control sound at a second point within the sound field among sounds formed from outputs of the first plural digital filters.

Still further objects of the present invention and practical merits obtained by the present invention will become more apparent from the description of the embodiments which will be given below with referred to the attached drawings.

### BRIEF DESCRIPTION OF THE DRAWINGS

FIG. 1 is a block diagram showing speaker array constituting speaker system used in home theater or AV system.

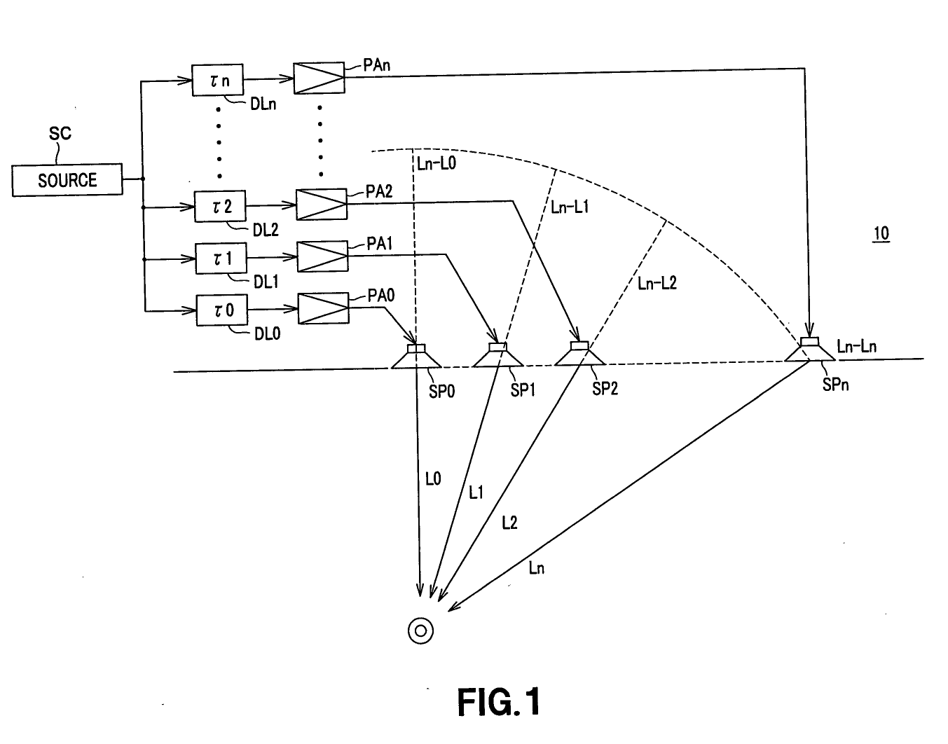

FIG. 2 is a plan view showing the state where sound field in the speaker system of 2 (two) channel stereo is formed.

FIG. 3 is a plan view showing the state where virtual image of sound field is formed in the speaker system of 2 (two) channel stereo.

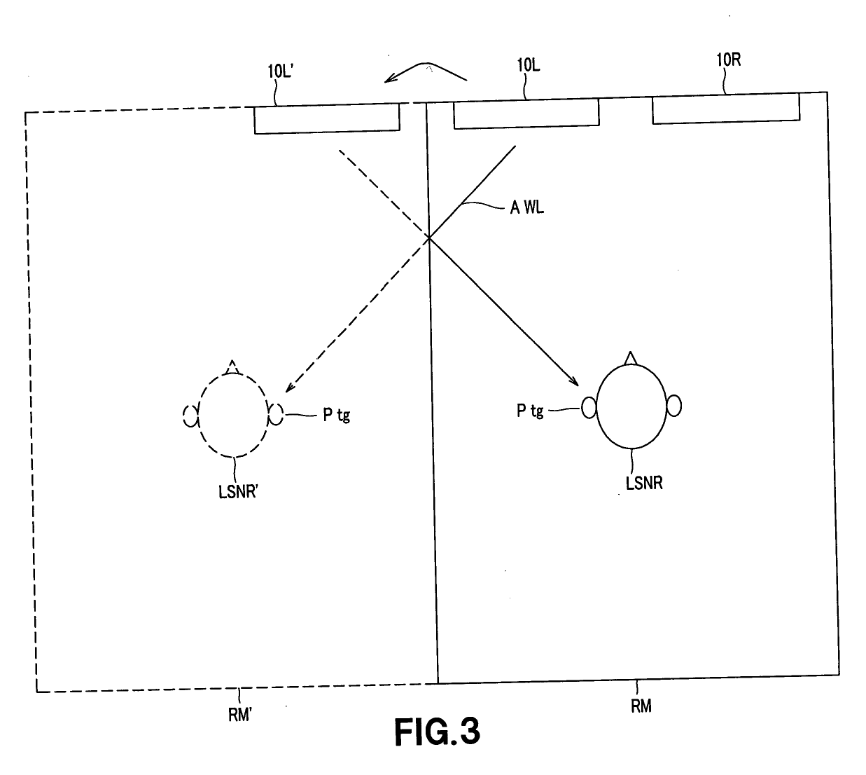

FIG. 4 is a plan view showing the state where sound field in the speaker system of 4 (four) channel stereo is formed.

FIG. 5 is a plan view showing the state where listener listens to sound radiated from the speaker system of 4 (four) channel stereo.

FIG. 6 is a view for explaining the state where the speaker array to which the present invention is applied is used to set sound pressure enhancement point Ptg and sound pressure reduction point Pnc at necessary places of the sound field.

FIG. 7A is a plan view showing the state where primary sound wave A WL and leakage sound A Wnc arrive at listener LSNR from the speaker array, FIG. 7B is a plan view showing the state where another sound wave AWs with position of the listener LSNR being as focal point is radiated from the speaker array, and FIG. 7C is a plan view showing the state where leakage sound A Wnc radiated from the speaker array is canceled by sound wave A Ws having anti-phase (opposite phase) and the same level at the position of listener LSNR.

FIG. 8 is a block diagram showing an example of a reproducing apparatus to which the present invention has been applied.

FIG. 9 is a block diagram showing another example of the reproducing apparatus to which the present invention has been applied.

FIG. 10 is a block diagram showing an example where speaker array to which the present invention has been applied is used to constitute a reproducing apparatus of 4 (four) channel stereo.

FIG. 11 is a plan view showing the state where leakage sound A Wnc of left channel is canceled by radiating sound wave A Ws from speaker array of the right channel.

FIG. 12 is a plan view showing sound field of an example where speaker arrays 10L, 10R are constituted by a single speaker array.

### BEST MODE FOR CARRYING OUT THE INVENTION

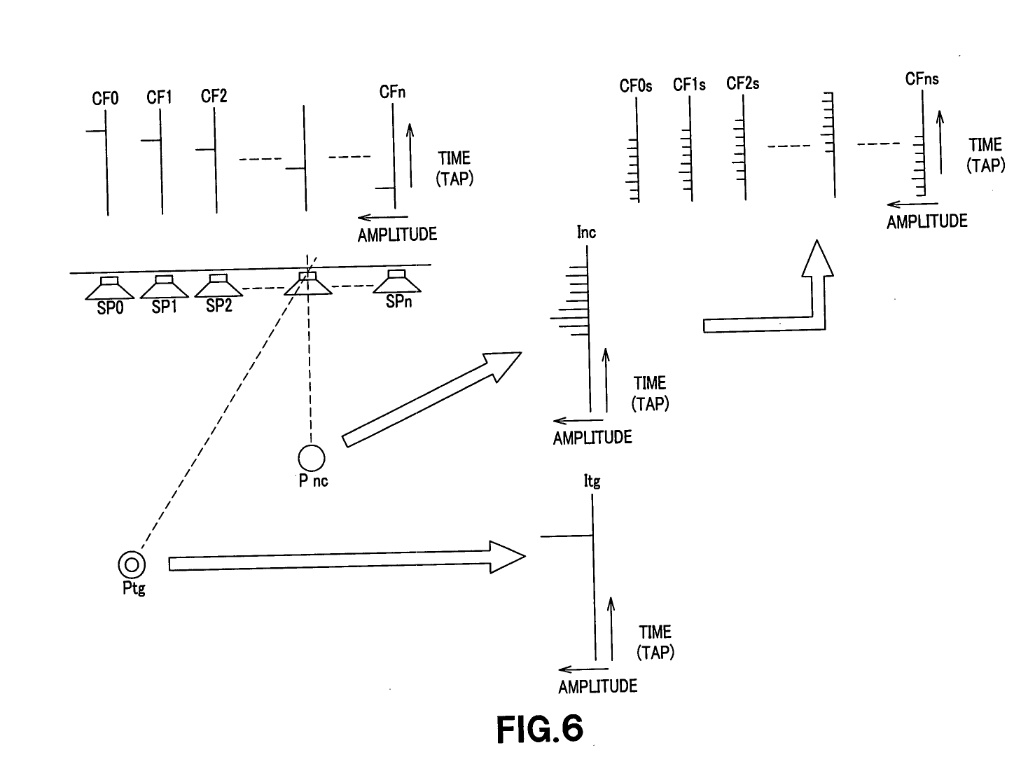

First, outline of the present invention will be explained with reference to FIG. 6. Here, for the brevity of explanation, explanation will be given by taking an example where plural speakers SP0 to SPn are arranged in line in a horizontal direction so that speaker array 10 is constituted, and the speaker array 10 thus constituted is applied to the previously described focus type speaker system shown in FIG. 6.

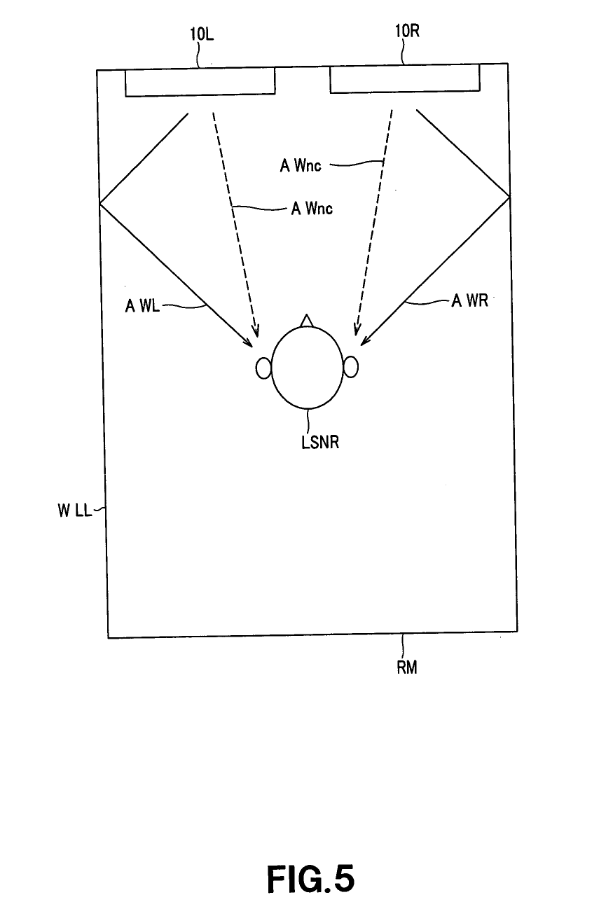

Here, when the position of the listener LSNR is assumed to be point Pnc, leakage sound A Wnc at this point Pnc is reduced. In this case, the reduction point Pnc also serves as focal point Ptg. Namely, reduction point Pnc of the leakage sound A Wnc and the focal point Ptg coincide with each other. However, since path of sound wave AW from the speaker array 10 up to the focal point Ptg and path of leakage sound A Wnc are different from each other also as shown in FIG. 5, the position of the focal point Ptg and reduction point Pnc of leakage sound A Wnc would differ from each other as shown in FIG. 6.

Respective delay circuits DL0 to DLn are assumed to be realized by FIR (Finite Impulse Response) digital filters. As shown in FIG. 6, filter coefficients of the FIR digital filters DL0 to DLn are assumed to be indicated by values CF0 to CFn.

Further, impulse is inputted to the FIR digital filters DL0 to DLn to measure output sound of the speaker array 10 at the point Ptg. In this example, this measurement is performed at a sampling frequency that reproduction system including FIR digital filters DL0 to DLn has, or at a sampling frequency more than that.

Thus, response signals measured at points Ptg, Pnc result in a sum signal in which sounds outputted from all speakers SP0 to SPn are propagated within space and are acoustically added. Further, at this time, for the purpose of facilitating explanation, signals outputted from the speakers SP0 to SPn are assumed to be impulse signals to which delays are given by the FIR digital filters DL0 to DLn. It is to be noted that, in the following explanation, response signal added via space propagation is called “spatially synthesized impulse response”.

Further, since delay components of FIR digital filters DL0 to DLn are set for the purpose of preparing focal point at the point Ptg, spatially synthesized impulse response Itg measured at the point Ptg results in a single large impulse as shown in FIG. 6. Moreover, since time waveform of frequency response (amplification part) Ftg of the spatially synthesized impulse response Itg has impulse shape, such time waveform becomes flat over the entire frequency band. Accordingly, the point Ptg becomes focal point in which sound pressure has been enhanced as described above.

It is to be noted that while, in practice, spatially synthesized impulse response Itg does not result in precise impulse by shift of the time axis prescribed by frequency characteristics of respective speakers SP0 to SPn, frequency characteristic change at the time of spatial propagation, reflection characteristic of the wall in the middle of path and/or sampling frequency, etc., such spatially synthesized impulse response is represented by ideal model for the brevity here.

On the other hand, it is considered that spatially synthesized impulse response Inc measured at reduction point Pnc results in synthesis of impulse components respectively having time axis information. As shown in FIG. 6, it is understood that the spatially synthesized impulse response Inc is a signal in which impulse components are dispersed with a width to a certain degree. It is to be noted that while impulse response Inc is equidistantly arranged pulse train in FIG. 6, the intervals of the pulse train are not generally equal.

It is considered that the spatially synthesized impulse response Inc is based on spatial FIR digital filter having filter coefficients CF0s to CFns as shown in FIG. 6. Thus, the spatially synthesized impulse response can be realized by speaker array in which the reduction point Pnc is caused to be focal point. Namely, if speaker array using FIR digital filter is prepared to set filter coefficients CF0s to CFns of the FIR digital filter to valves shown in FIG. 6, it is possible to obtain spatially synthesized impulse response Inc in which the reproduction point Pnc is caused to be focal point.

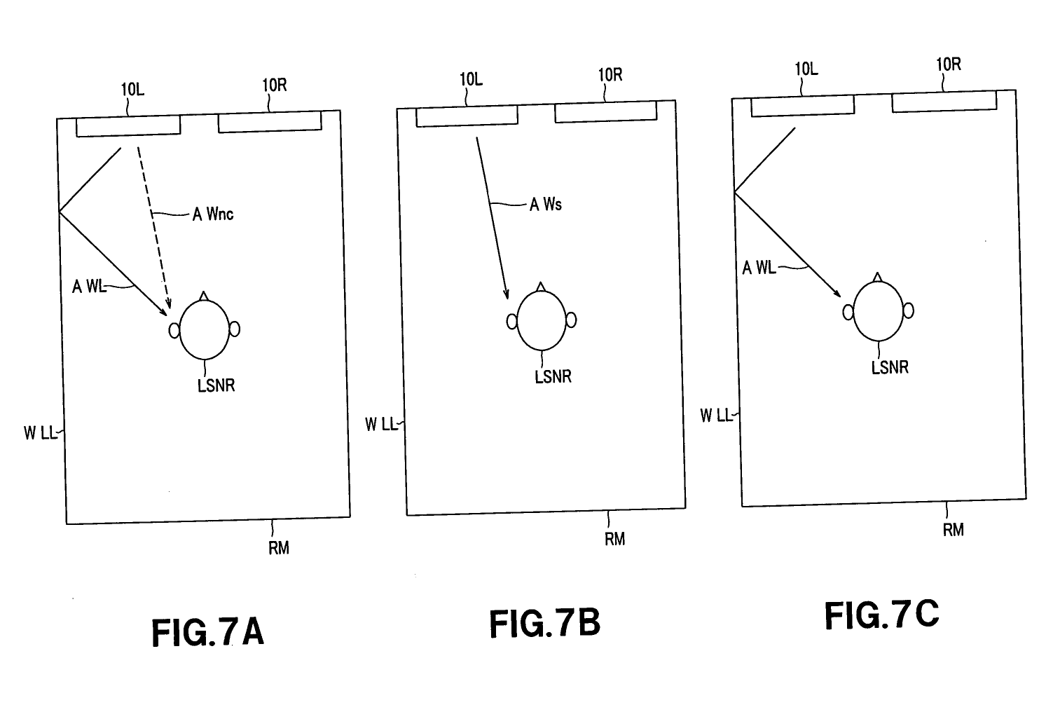

In view of the above, in the present invention, as shown in FIGS. 7A to 7C, for example, leakage sound A Wnc is reduced. It is to be noted that only the left channel is indicated in FIGS. 7A to 7C. Namely, when primary sound wave A WL and leakage sound A Wnc arrive at listener LSNR from the speaker array 10L as shown in FIG. 7A, another sound wave AWs in which reduction point Pnc (position of listener LSNR) is caused to be focal point is radiated from the speaker array 10L as shown in FIG. 7B. The sound wave AWs shown in FIG. 7B has frequency characteristic and level which are equal to those of leakage sound A Wnc, but has phase opposite thereto. The sound wave AWs is formed by another FIR digital filter having filter coefficients CF0s to CFns of FIG. 6.

As described above, another sound wave A Ws in which reduction point Pnc (position of listener LSNR) is caused to be focal point, which is radiated from the speaker array 10L, has frequency characteristic and level which are equal to leakage sound A Wnc and phase opposite thereto, whereby leakage sound A Wnc radiated from the speaker array 10L is canceled by sound wave AWs having opposite phase and the same level at the position of the listener LSNR as shown in FIG. 7C so that only primary sound wave A WL is heard to the listener LSNR.

### First Embodiment

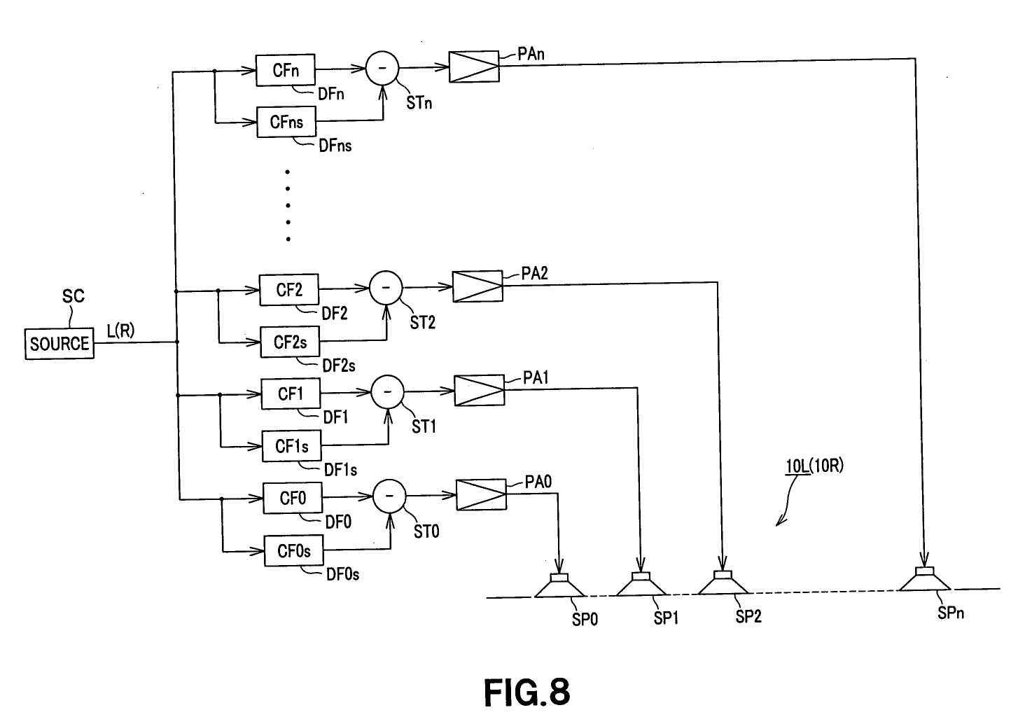

Then, the first embodiment to which the present invention has been applied to a reproducing apparatus will be explained with reference to FIG. 8. It is to be noted that only the left channel in the 2 (two) channel stereo is indicated in FIG. 8.

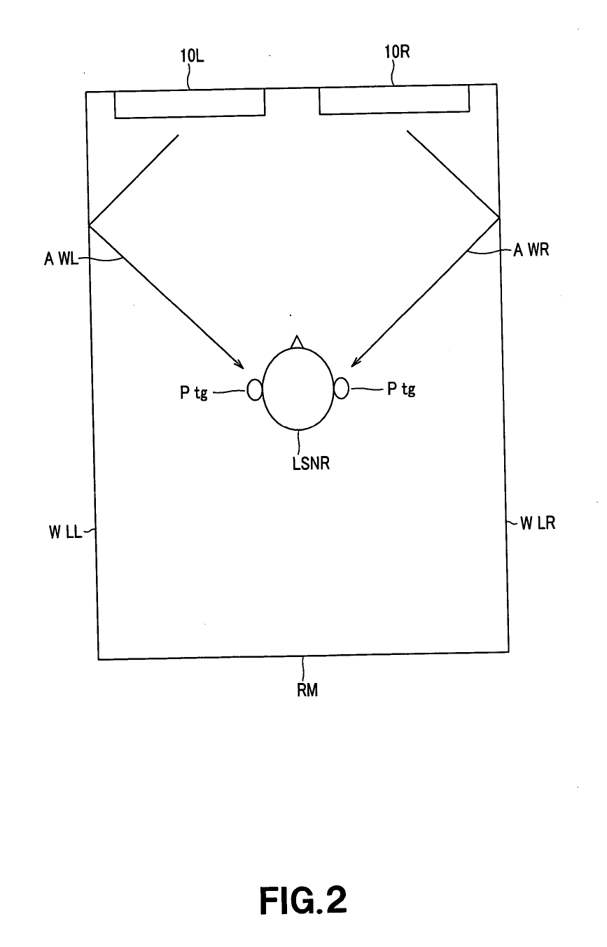

Namely, digital audio signals L, R of left and right channels are taken out from source SC. The signal L of the left channel is delivered to FIR digital filters DF0 to DFn. The FIR digital filters DF0 to DFn serve to implement predetermined delays to audio signals L. As shown in the previously described FIG. 2, their delay times τ0 to τn are set so that sound wave A WL radiated from the speaker array 10L is reflected on the wall surface WLL of the left side and focal point Ptg is thus formed at the position of the listener LSNR. Moreover, setting of the delay times τ0 to τn is realized by setting filter coefficients CF0 to CFn of the FIR digital filters DF0 to DFn to predetermined values.

Output signals of the FIR digital filters DF0 to DFn are delivered to power amplifiers PA0 to PAn through subtraction circuits ST0 to STn. The output signals thus delivered are caused to undergo D/A (Digital to Analog) conversion, and are then power-amplified or class-D amplified. The amplified outputs thus obtained are delivered to speakers SP0 to SPn.

Further, the digital audio signal L from the source SC is delivered to other (different) FIR digital filters DF0s to DFns, and their filter outputs are delivered to the subtraction circuits ST0 to STn. In this case, the FIR digital filters DF0s to DFns have filter coefficients CF0s to CFns which have been explained with reference to FIGS. 6 and 7, and serve to realize spatially synthesized impulse response Inc shown in FIG. 6. In addition, in the subtraction circuits ST0 to STn, outputs of the filters DF0s to DFns are subtracted from outputs of the filters DF0 to DFn.

Moreover, although not shown, digital audio signal R of the right channel which has been taken out from the source SC is similarly processed, and is delivered to the speaker array 10R of the right channel.

By provision of such a configuration, primary sound wave A WL is radiated from the speaker array 10L by signals delivered to the speakers SP0 to SPn through FIR digital filters DF0 to DFn among audio signals L of the left channel which have been outputted from the source SC. The sound wave A WL is reflected on the wall surface WLL, as shown in FIG. 7A, for example, and is then focused on the position of the listener LSNR.

It should be noted that even if only such an approach is employed, leakage sound A Wnc would be produced from the speaker array 10L as shown in FIG. 7A. At this time, sound wave AWs is radiated from the speaker array 10L by signals delivered to speakers SP0 to SPn through FIR digital filters DF0s to DFns among signals L of the left channel which have been outputted from the source SC. The sound wave A Ws directly arrives at the position of listener LSNR, as shown in FIG. 7B, for example, and is focused thereat.

By setting filter coefficients CF0s to CFns, the spatially synthesized impulse response of the sound wave A Ws is caused to be equal to spatially synthesized impulse response Inc of leakage sound A Wnc. At this time, outputs of the filters DF0s to DFns are phase-inverted with respect to outputs of the filters DF0 to DFn in the subtraction circuits ST0 to STn, and outputs thus obtained are added.

As a result, at the position of the listener LSNR, the sound wave A Ws has the same frequency component as that of the leakage sound A Wnc and phase opposite thereto. Thus, leakage sound A Wnc is canceled by the sound wave A Ws. Accordingly, as shown in FIG. 7C, primary sound wave A WL arrives at the listener LSNR, but listener LSNR hardly listens to leakage sound A Wnc. Moreover, similar operation is performed also with respect to the speaker array 10R. Even if leakage sound might be produced in sound wave A WR radiated from the speaker array 10R, its leakage sound is canceled. Thus, listener LSNR hardly perceives that leakage sound.

Thus, in accordance with the speaker array apparatus shown in FIG. 8, it is possible to perform reproduction of 2 (two) channel stereo by speaker arrays 10L, 10R disposed at the forward side of the listener LSNR. In addition, at this time, a signal equivalent to the leakage sound A Wnc is formed to subtract this signal with respect to (from) primary audio signal so that leakage sound A Wnc is not heard to the listener LSNR. Accordingly, it is possible to prevent lowering of sound quality by the leakage sound A Wnc.

It is to be noted that in the case where the speaker array 10L radiates primary sound wave A WL, there is the possibility that when sound wave A Ws is radiated so that leakage sound A Wnc is produced as shown in FIG. 7A, a portion thereof arrives at the listener LSNR through the same path as that of sound wave A WL shown in FIG. 7A so that such sound portion may result in new leakage sound. However, since level of the leakage sound A Wnc is small as compared to the primary sound wave A WL, level of sound wave A Ws for canceling its leakage sound A Wnc is also small. Since a portion of the sound wave A Ws having small level results in new leakage sound, level of the leakage sound is sufficiently small. Therefore, such leakage sound can be neglected.

### Second Embodiment

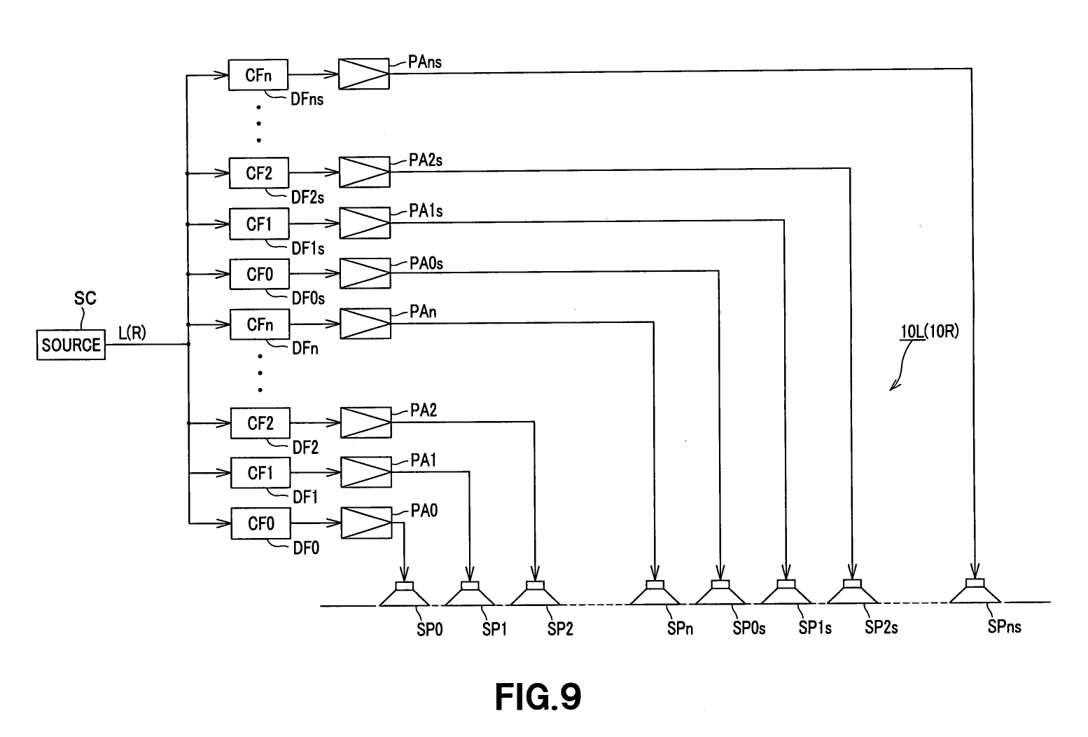

Then, the second embodiment of the present invention will be explained with reference to FIG. 9.

The example shown in FIG. 9 is directed to the case where sound wave A Ws having the same component and the same level as those of leakage sound A Wnc and phase opposite thereto is radiated from speakers different from the speakers SP0 to SPn to cancel leakage sound A Wnc. It is to be noted that, also in this example, only the left channel in the 2 (two) channel stereo is shown.

Namely, the speaker array 10L is composed of first set of spakers SP0 to SPn, and second set of speakers SP0s to SPns. Further, digital audio signals L, R of left and right channels are taken out from the source SC. The signal L of the left channel is delivered to speakers SP0 to SPn through FIR digital filters DF0 to DFn and power amplifiers PA0 to PAn. In addition, the signal L of the left channel from the source SC is delivered to speakers SP0s to SPns through FIR digital filters DF0s to DFns and power amplifiers PA0s to PAns.

In this case, FIR digital filters DF0 to DFn, DF0s to DFns are caused to be those similar to the first embodiment. Moreover, connection between power amplifiers PA0s to PAns and speakers SP0s to SPns is caused to have opposite polarity with respect to connection between power amplifiers PA0 to PAn and speakers SP0 to SPn.

In accordance with such configuration, primary sound wave A WL is radiated from speakers SP0 to SPn. The sound wave thus radiated is reflected on the wall surface WLL, as shown in FIG. 7A, for example, and is then focused on the position of the listener LSNR. Further, at this time, leakage sound A Wnc is produced from the speakers SP0 to SPn.

At this time, since outputs of the FIR digital filters DF0s to DFns are delivered to the speakers SP0s to SPns in the state of opposite polarity through power amplifiers PA0s to PAns, sound wave AWs having frequency component and level which are the same as those of leakage sound A Wnc and phase opposite thereto is radiated, as shown in FIG. 7B, from speakers SP0s to SPns, and the leakage sound A Wnc is canceled by the sound wave A Ws. Accordingly, as shown in FIG. 7C, primary sound wave A WL arrives at the listener LSNR, but listener hardly listens to the leakage sound A Wnc.

Moreover, similar operation is performed also with respect to the speaker array 10R. Even if leakage sound is produced in sound wave A WR radiated from the speaker array 10R, that leakage sound is canceled. Thus, listener LSNR hardly perceives the leakage sound.

In a manner as stated above, in the speaker array apparatus of FIG. 9, since leakage sound A Wnc produced by the speakers SP0 to SPn is canceled by sound wave AWs radiated from the speakers SP0s to SPns, it is possible to perform reproduction of 2 (two) channel stereo in which leakage sound A Wnc has sufficiently suppressed.

### Third Embodiment

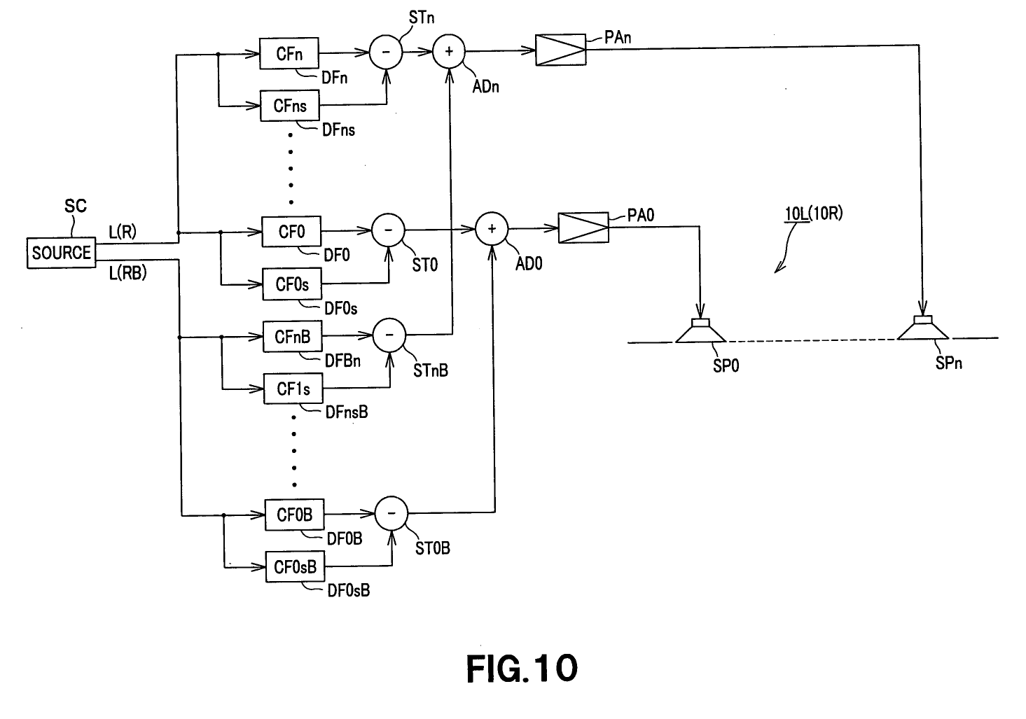

Then, the third embodiment of the present invention will be explained with reference to FIG. 10.

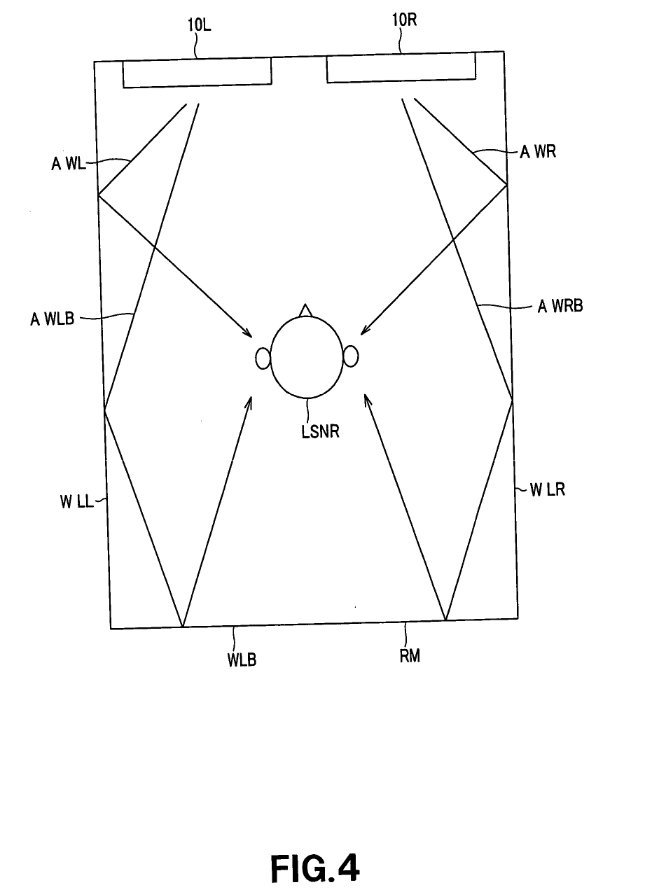

The example shown in FIG. 10 is directed to the case where the previously described 4 (four) channel stereo shown in FIG. 4 is realized, and its leakage sound is suppressed. It is to be noted that, in this example, only left forward channel and left backward channel in the 4 (four) channel stereo are indicated.

Namely, digital audio signals L, LB, R, RB of left forward channel, left backward channel, right forward channel and right backward channel are taken out from the source SC. Further, with respect to the signal L of the left forward channel, FIR digital filters DF0 to DFn, DF0s to DFns, and subtraction circuits ST0 to STn are constituted in a manner similar to those in FIG. 8, and outputs of the subtraction circuits ST0 to STn are delivered to speakers SP0 to SPn of the speaker array 10L of the left channel through addition circuits AD0 to ADn, and through power amplifiers PA0 to PAn.

Further, with respect to signal LB of the left backward channel, FIR digital filters DF0B to DFnB, DF0sB to DFnsB, and subtraction circuits ST0B to STnB are constituted in a manner similar to those in the left forward channel, and outputs of the subtraction circuits ST0B to STnB are delivered to adding circuits AD0 to ADn.

Accordingly, as shown in FIG. 4, filter coefficients CF0 to CFn, CF0LB to CFnLB of the digital filters DF0 to DFn, DF0LB to DFnLB are set to predetermined values so that sound waves A WL, A WLB of left forward channel and left backward channel are radiated from the speaker array 10L. As a result, the sound wave AWL is reflected on the wall surface WLL, and is then focused on the position of the listener LSNR. Thus, the sound wave A WLB is reflected on the wall surface WLL and the backward wall surface, and is then focused on the position of the listener LSNR.

At this time, leakage sounds A Wnc, A Wnc of left forward channel and left backward channel based on audio signals L, LB should be radiated from the speaker array 10L. However, these leakage sounds A Wnc, A Wnc are respectively canceled by outputs of the FIR digital filters DF0s to DFns, DF0sB to DFnsB. Thus, there is no possibility that such leakage sounds are heard to listener.

Further, also with respect to the right forward channel and right backward channel, configuration is similarly employed. As shown in FIG. 4, sound wave A WR of the right forward channel and sound wave A WRB of the right backward channel are radiated from the speaker array 10R, and are focused on the position of the listener LSNR. In addition, at this time, leakage sounds A Wnc, A Wnc of the right forward channel and the right backward channel based on audio signals R, RB are respectively canceled. Thus, there is no possibility that such leakage sounds may be heard to the listener LSNR.

Accordingly, in accordance with the speaker array apparatus shown in FIG. 10, it is possible to perform reproduction of 4 (four) channel stereo in which leakage sound A Wnc has been sufficiently suppressed.

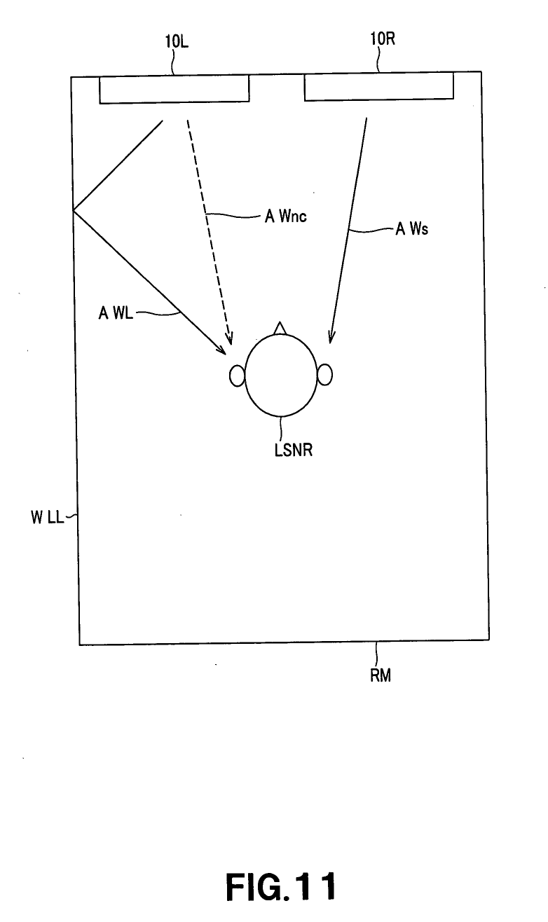

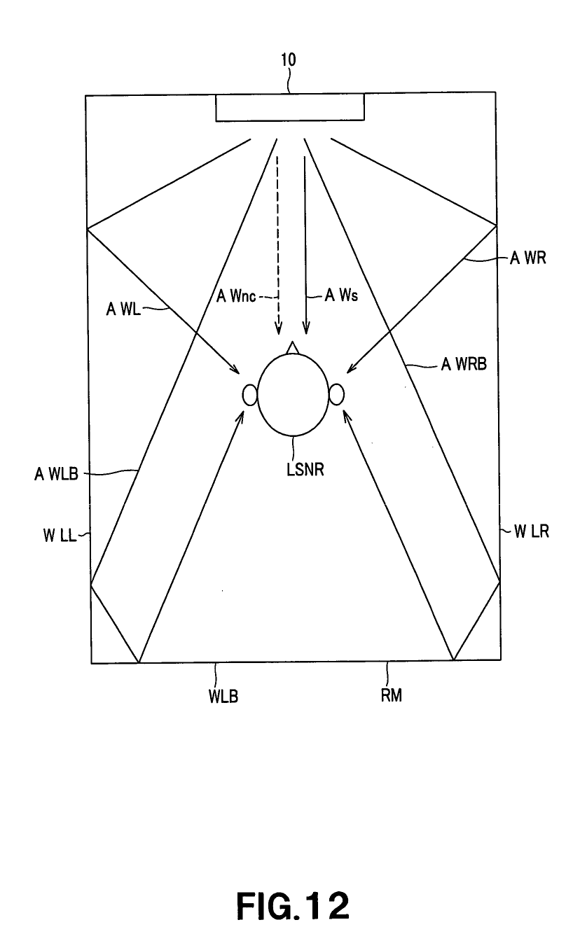

While leakage sound A Wnc of the left channel is canceled by radiating sound wave A Ws from the speaker array 10L of the left channel as shown in FIGS. 7A to 7C in the above-described example, leakage sound A Wnc of the left channel may be canceled by irradiating sound wave A Ws from the speaker array 10R of the right channel as shown in FIG. 11. In addition, the speaker arrays 10L, 10R may be constituted as a single speaker array 10 as shown in FIG. 12.

It is to be noted that while the present invention has been described in accordance with certain preferred embodiments thereof illustrated in the accompanying drawings and described in the above description in detail, it should be understood by those ordinarily skilled in the art that the invention is not limited to embodiments, but various modifications, alternative constructions or equivalents can be implemented without departing from the scope and spirit of the present invention as set forth by appended claims.

### INDUSTRIAL APPLICABILITY

As described above, in accordance with the present invention, since leakage sound produced in the speaker array apparatus is canceled by forming a signal equivalent to the leakage sound, it is possible to prevent lowering of sound quality by leakage sound.

1. A reproducing method for reproducing an audio signal, comprising the steps of:
delivering an audio signal to a first plurality of digital filters;
delivering outputs of the first plurality of digital filters to a plurality of speakers, respectively, constituting a speaker array to form a sound field;
respectively setting predetermined delay times at the first plurality of digital filters so that respective propagation delay times required until the audio signal arrives at a first point within the sound field through the first plurality of digital filters and the respective plurality of speakers coincide with each other;
delivering the audio signal to a second plurality of digital filters;
respectively delivering outputs of the second plurality of digital filters to the plurality of speakers; and
respectively setting predetermined transfer characteristics at the second plurality of digital filters so as to control sound at a second point within the sound field among sounds formed from outputs of the first plurality of digital filters.

2. The reproducing method for reproducing an audio signal as set forth in claim 1,
wherein a sound wave radiated from the speaker array is reflected on a wall surface, and arrives at the first point.

3. The reproducing method for reproducing an audio signal as set forth in claim 1,
wherein the second point is at substantially the same location as the first point.

4. A reproducing method for reproducing an audio signal, comprising:
delivering an audio signal to a first plurality of digital filters;
delivering outputs of the first plurality of digital filters to a respective plurality of speakers constituting a first speaker array to form a sound field;
respectively setting predetermined delay times at the first plurality of digital filters so that respective propagation delay times required until the audio signal arrives at a first point within the sound field through the first plurality of digital filters and the respective plurality of speakers of the first speaker array coincide with each other;
delivering the audio signal to a second plurality of digital filters;
delivering outputs of the second plurality of digital filters to a respective plurality of speakers constituting a second speaker array; and
respectively setting predetermined transfer characteristics at the second plurality of digital filters so as to control sound at a second point within the sound field among sounds formed from outputs of the first plurality of digital filters.

5. The reproducing method for reproducing an audio signal as set forth in claim 4,
wherein a sound wave radiated from the first speaker array is reflected on a wall surface, and arrives at the first point.

6. The reproducing method for reproducing an audio signal as set forth in claim 4,
wherein the second point is at substantially the same location as the first point.

7. A reproducing apparatus for reproducing an audio signal, comprising:
a first plurality of digital filters each supplied with an audio signal;
a second plurality of digital filters each supplied with the audio signal; and
a speaker array in a configuration in which plurality of speakers are arranged,
in which outputs of the first plurality of digital filters are delivered to the respective plurality of speakers to form a sound field,
in which predetermined delay times are set at the first plurality of digital filters so that respective propagation times required until the audio signal arrives at a first point within the sound field through the first plurality of digital filters and the respective plurality of speakers coincide with each other,
in which outputs of the second plurality of digital filters are delivered to the respective plurality of speakers,
and in which predetermined transfer characteristics are set at the second plurality of digital filters so as to control sound at a second point within the sound field among sounds formed from outputs of the first plurality of digital filters.

8. The reproducing apparatus for reproducing an audio signal as set forth in claim 7,
wherein a sound wave radiated from the speaker array is reflected on a wall surface, and arrives at the first point.

9. The reproducing apparatus for reproducing an audio signal as set forth in claim 8,
wherein the second point is at substantially the same location as the first point.

10. The reproducing apparatus for reproducing an audio signal as set forth in claim 7,
further comprising a plurality of subtraction circuits respectively supplied with outputs of the first plurality of digital filters and outputs of the second plurality of digital filters, in which outputs of the plural plurality of subtraction circuits are respectively delivered to the plural speakers.

11. A reproducing apparatus for reproducing an audio signal, including:
a first plurality of digital filters each supplied with an audio signal;
a second plurality of digital filters each supplied with the audio signal;
a first speaker array in a first of the configuration in which plurality of speakers are arranged; and
a second speaker array in a first configuration in which plurality of speakers are arranged
wherein outputs of the first plurality of digital filters are delivered to the respective plurality of speakers constituting the first speaker array to form a sound field,
wherein predetermined delay times are set at the first plurality of digital filters so that respective propagation delay times required until the audio signal arrives at a first point within the sound field through the first plurality of digital filters and the respective speakers of the first speaker array coincide with each other,
wherein the audio signal is delivered to the respective second plurality of digital filters
wherein outputs of the second plurality of digital filters are delivered to the respective plurality of speakers constituting the second speaker array, and
wherein predetermined transfer characteristics are set at the second plurality of digital filters so as to control sound at a second point within the sound field among sounds formed from outputs of the first plurality of digital filters.

12. The reproducing apparatus for reproducing an audio signal as set forth in claim 11,
wherein a sound wave radiated from the first speaker array is reflected on a wall surface, and arrives at the first point.

13. The reproducing apparatus for reproducing an audio signal as set forth in claim 12,
wherein the second point is at substantially the same location as the first point.
